(19) United States
(12) Patent Application Publication
(10) Pub. No.: US 2006/0203312 A1
(43) Pub. Date: Sep. 14, 2006

(54) Enriched photo viewing experience of digital photographs

(75) Inventors: Bartel Marinus Van De Sluis, Eindhoven (NL); Elmo Marcus Attila Diederiks, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., 5621 BA Eindhoven (NL)

(21) Appl. No.: 10/566,962

(22) PCT Filed: Jul. 26, 2004
(86) PCT No.: PCT/IB04/51293

§ 371 Date: Jan. 26, 2006

Related U.S. Application Data
(60) Provisional application No. 60/490,836, filed on Jul. 29, 2003.

(51) Int. Cl. G03F 3/10

(52) U.S. Cl. 358/527

(57) ABSTRACT

A method for viewing digital still photographs is provided. The method including: inputting at least one digital data file representing a digital still photograph, the at least one digital data file and location stamp indicating a time when the photograph was taken or a location where the photograph was taken, digital still photograph; and altering an ambient characteristic based on at least one of the time and location stamps.

The present invention relates generally to viewing of digital photographs, and more particularly, to altering an ambient characteristic in an area proximate a display of the digital photographs based at least in part on one or both of a time when the photograph was taken and a location where the photograph was taken.

Digital cameras are known in the art to have an internal clock for time stamping a digital data file associated with a digital photograph. The time stamp is useful for determining the time when the digital photograph was taken. Similarly, digital cameras are also known in the art to have a GPS receiver for receiving GPS signals. These cameras can add a location stamp to a digital data file associated with a digital photograph. The location stamp is useful for determining the location where the digital photograph was taken.

Furthermore, apparatus, such as a personal computer, a television, a web tablet, and a personal digital assistant, are known for storing and viewing digital photograph collections. Typically, the digital photographs are viewed in a home surrounding and shown in a slide show. However, such apparatus do not take advantage of the time and/or location stamps to enrich the viewing experience of the digital photographs.

Therefore it is an object of the present invention to provide an enriched viewing of digital still photographs.

Accordingly, a system for viewing digital still photographs is provided. The apparatus comprising: data input means for inputting at least one digital data file representing a digital still photograph, the at least one digital data file having at least one of a time and location stamp indicating a time when the photograph was taken or a location where the photograph was taken, respectively; a display for displaying the digital still photograph; digital still photograph rendering means for inputting the at least one digital data file to the display for rendering of the corresponding digital still photograph on the display; and ambient alteration means for altering an ambient characteristic based on at least one of the time and location stamps.

The data input means can be a media drive for reading the at least one digital data file from a media contained in the media drive. The media drive can be one of a CD player, DVD player, floppy drive, and digital camera media card reader. The data input means can also comprise a modem operatively connected to one of a network, storage device, and digital still camera. The data input means can further comprise a connector operatively connected through a cable to one of a network, storage device, and digital still camera. The data input means can still further comprise a connector wirelessly connected to one of a network, storage device, and digital still camera.

The ambient alteration means can comprise a lighting system, in which case the ambient characteristic can comprise an ambient lighting in an area proximate the display. The ambient lighting system can change the ambient lighting to reproduce a lighting characteristic of at least one of the time when the digital photograph was taken and the location where the digital photograph was taken.

The ambient alteration means can also comprise an audio rendering system and at least one speaker operatively connected thereto, in which case the ambient characteristic comprises reproducing audio in an area proximate the display. The reproduced audio can be characteristic of at least one of the time when the digital photograph was taken and the location where the digital photograph was taken.

The apparatus can further comprise at least one other display in an area proximate the display, in which case the ambient characteristic comprises the at least one other display. A display on the one other display can be representative of a historical period within the time when the digital photograph was taken. A display on the one other display can also be representative of a geographical location where the digital photograph was taken. The ambient alteration means can also comprise an advertisement generation means for generating at least one of an audio or visual advertisement on the at least one other display.

Also provided is an apparatus for viewing digital still photographs. The apparatus comprising: data input means for inputting at least one digital data file representing a digital still photograph, the at least one digital data file having at least one of a time and location stamp indicating a time when the photograph was taken or a location where the photograph was taken, respectively; digital still photograph rendering means for inputting the at least one digital data file to a display for rendering of the corresponding digital still photograph; and signal generation means for generation of a signal for altering an ambient characteristic based on at least one of the time and location stamps.

Still further provided is a method for viewing digital still photographs. The method comprising: inputting at least one digital data file representing a digital still photograph, the at least one digital data file having at least one of a time and location stamp indicating a time when the photograph was taken or a location where the photograph was taken, respectively; displaying the digital still photograph; and altering an ambient characteristic based on at least one of the time and location stamps.

The altering comprises altering an ambient lighting in an area proximate the display. The altering of the ambient lighting can comprise at least one of reproducing a lighting for the time when the digital photograph was taken and the location where the digital photograph was taken.

The altering can comprise reproducing audio in an area proximate the display. The audio reproduced can be characteristic of at least one of the time when the digital photograph was taken and the location where the digital photograph was taken.

The altering can also comprise controlling at least one other display in an area proximate the display. The controlling can comprise displaying indicia on the one other display representative of a historical period within the time when the digital photograph was taken. The controlling can also comprise displaying indicia on the one other display representative of a geographical location where the digital photograph was taken. The controlling can still further comprise displaying an advertisement on the at least one other display.

Still provided is a display comprising: a display portion for rendering images; and an illumination means separate from the display portion for illuminating an area proximate the display portion to change the lighting in the area.

Still yet further provided is a speaker comprising: an audio reproduction means for reproducing audio in an area proximate the audio reproduction means; and an illumination means for illuminating the area to change the lighting in the area.

Also provided are a computer program product for carrying out the methods of the present invention and a program storage device for the storage of the computer program product therein.

These and other features, aspects, and advantages of the apparatus and methods of the present invention will become better understood with regard to the following description, appended claims, and accompanying drawings where:

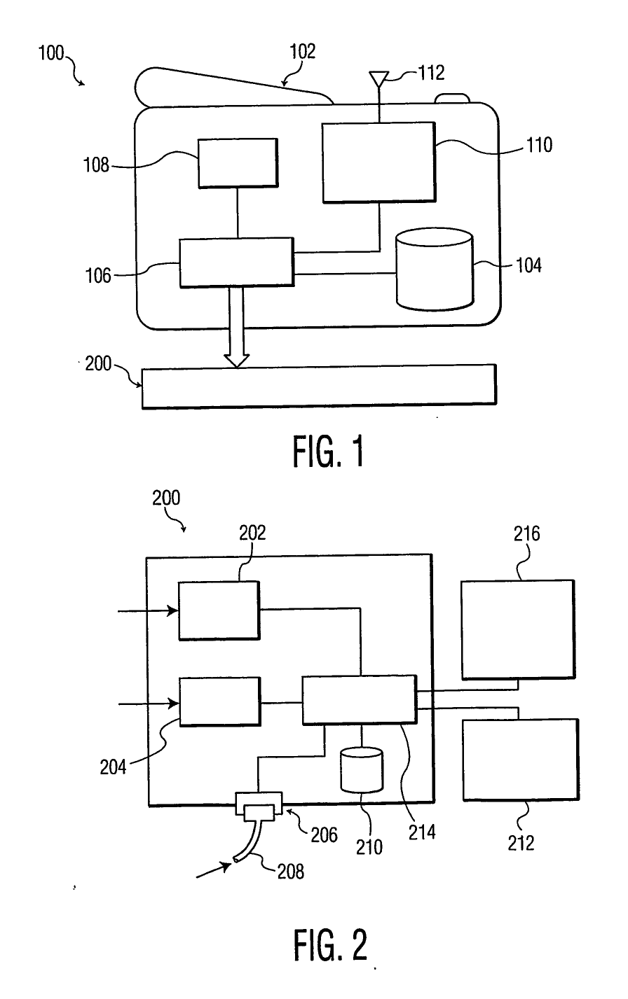

FIG. 1 illustrates a schematic view of an apparatus for enriched viewing of digital photographs and a digital camera for capturing digital photographs having at least one of a location and time stamp.

FIG. 2 illustrates a schematic view of the apparatus of FIG. 1.

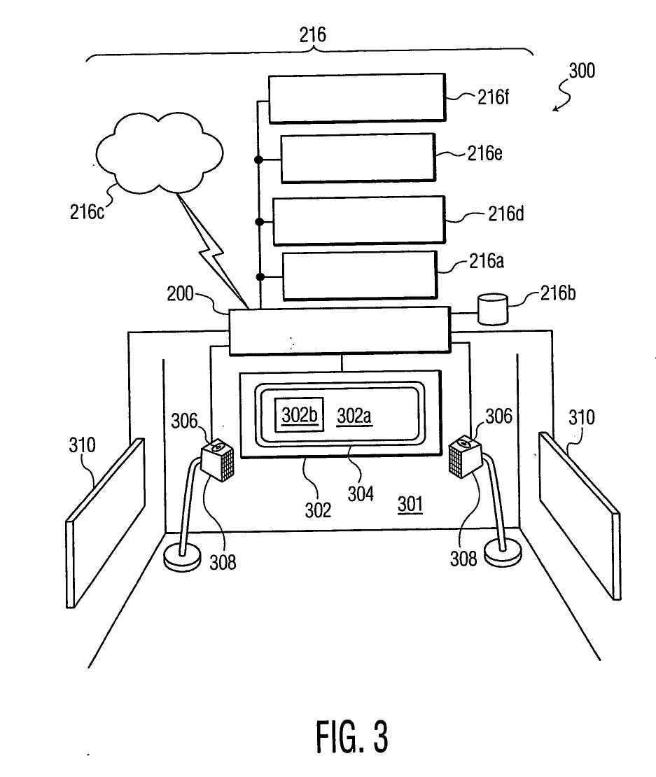

FIG. 3 illustrates a schematic view of an embodiment of a system for enriched viewing of digital photographs having the apparatus of FIG. 1.

Although this invention is applicable to numerous and various types of apparatus, it has been found particularly useful in the environment of televisions for home use. Therefore, without limiting the applicability of the invention to televisions for home use, the invention will be described in such environment. Those skilled in the art will appreciate that other apparatus can be used to carry out the methods of the present invention, such as a personal computer, an Internet connected CD/DVD player, a laptop computer, a web tablet computer, a personal digital assistant, and a digital camera.

Referring now to FIG. 1, there is illustrated a schematic of an embodiment of a system for use in viewing digital still photographs. The system being generally referred to by reference numeral 100. The system 100 comprises a digital camera 102 for taking digital still photographs. For purposes of this disclosure, “taking” of digital still photographs includes capturing a scene with an image-capturing device (not shown) and converting the scene to digital data. “Taking” digital still photographs can also mean storing the digital data on a storage device 104, such as a media card or CD operatively connected to the digital camera 102. The image-capturing device for taking the digital photographs can include a CCD under the control of a processor 106 and operatively connected to the storage device 104, preferably by way of the processor 106. The operation of digital cameras to capture image data and store the same are well known in the art. Various formats of digital data are known in the art for storing digital image files, such as JPEG and TIF.

The digital camera 102 also can have means for time and/or location stamping of the digital data file associated with the digital still photograph. Typically, the digital camera 102 will take a plurality of digital still photographs. The time and location stamps indicate a time when the photograph was taken and a location where the photograph was taken, respectively. The time and location stamps can be appended to the digital data file for the digital still photograph or contained in a header, both of which are well known in the art. The time stamp can be provided by a clock 108 operatively connected to the processor 106 and can include the time as well as the date when the digital photograph is taken. The clock 108 may be configured to change its time to reflect a local time zone determined from the location stamp, as is known in the art. The location stamp can be provided by a position detection means 110 such as a GPS receiver that is also operatively connected to the processor 106. The GPS receiver includes an antenna 112 that receives GPS location signals from a GPS satellite (not shown) and supplies such location signals to the processor 106. The processor 106 can convert such location and time stamps to a proper format for use with the system 100, if necessary. Photographic images which are digitized, such as by scanning, can also be used in the apparatus and methods described herein. However, such digitized images would have to be manually stamped with time and location stamps, if known.

The system 100 further includes a photograph rendering system 200 having a data input means for inputting the digital data files from the digital camera 102, either directly or indirectly. The photograph rendering means 200 can be any apparatus that is able to render and display digital photographs on a display. The digital photographs may be rendered “on the fly” or retrieved from a storage device. The storage device can be integral with the photograph rendering device 200 or remote therefrom. The digital photographs may also be retrieved via a remote network, such as from an Internet address.

Referring now to FIG. 2, there is illustrated a schematic illustration of an embodiment of the photograph rendering device 200. The data input means can be any device, devices, or means for inputting the digital data files taken by the camera to the photograph rendering device 200 for viewing, such means may be wired or wireless. For example, the data input means can be a media drive 202 for reading the digital data files from a media contained in the media drive 202. The media drive 202 can be a CD player, DVD player, floppy drive, or a digital camera media card reader. Alternatively, the data input means can be a modem 204 operatively connected to a network, storage device, or directly to the digital still camera 102. The digital data files can be transmitted to the modem 204 over a wired communication link, such as a cable or telephone line, or through a wireless technology such as a satellite, or a cellular phone network. The data input means can also be a connector 206 operatively connected through a cable 208 to a network, storage device, or directly to the digital still camera. The connector 206 may also support USB, Bluetooth, and WiFi connections. Furthermore, the connector 206 may also be able to receive cellular transmissions of digital photographs, possibly from cellular phones having the capability of taking digital still photographs. The apparatus 200 further has a storage device 210, such as a hard drive, for storing program instructions and data, such as digital data files corresponding to the digital still photographs. The digital data files may be stored on the hard drive 210 for further processing as discussed below or processed “on the fly” without being first stored. The apparatus 200 can also include an instruction input device 212, such as a remote control, keyboard, touchpad, mouse, tablet pen or the like, for entering instructions into the apparatus 200. Such instruction input device 212 may be operatively connected to the apparatus 200 by either a wired or wireless communication link, such as an infrared remote control or a wired keyboard. The above-mentioned components of the apparatus 200 are all preferably under the control of a processor 214. The apparatus 200 is preferably connected to one or more networks/systems/databases 216, shown schematically in FIG. 2 by a single box 216.

Referring now to FIG. 3, there is shown a system for practicing the methods of the present invention, the system being referred to generally by reference numeral 300. The components of the system 300 are shown separable from the apparatus 200 but may also be formed integrally therewith either in whole or in part. Furthermore, the components of system 300 can be integrally formed in a structure, such as a room 301 of a home or stand-alone as is shown in FIG. 3. The system 300 includes a display 302 for displaying the digital still photographs. The display 302 can be a television, monitor, computer display, LCD screen or the like. The photograph rendering apparatus 200 inputs the digital data files to the display for rendering of the corresponding digital still photographs on the display 302.

The system 300 further includes an ambient alteration means for altering an ambient characteristic based on at least one of the time and location stamps. The altering of one or more ambient characteristics serves to enrich the viewing experience of the digital still photographs. The ambient alteration means may be integrally formed in the photograph rendering apparatus 200, such as in the processor 214, or remote therefrom, and may also include one or more of the networks/systems/databases 216 operatively connected to the photograph rendering apparatus 200. For purposes of this disclosure, an ambient characteristic is anything that can be viewed or otherwise sensed in an area proximate to the display 302. Although such ambient characteristics are shown and described with regard to visual and audio changes in the area proximate the display 302, such is given by way of example only and not to limit the scope or spirit of the present invention. For example, the ambient characteristic can be an odor that is reproduced in the area proximate the display. The altering of one or more ambient characteristics while viewing a digital still photograph on the display 302 can be automatically carried out by the system 300 but is preferably carried out upon a manual instruction by a viewer, such as selecting an “Enriched Viewing” button on the apparatus 200 or instruction input device 212.

In a first embodiment, the ambient characteristic comprises an ambient lighting in an area proximate the display. In this embodiment, the ambient alteration means can comprise a lighting system 216a that can set the color and/or intensity of the lighting in the area proximate the display 302. Such lighting systems 216a are disclosed in Netherlands Patent Application Serial Nos. NL020628, NL020627, and NL030258, (corresponding to Attorney Docket Numbers 609511, 609,515, and 610538, respectively) the entire contents of which are incorporated herein by their reference. As discussed above, the lighting system 216a can be integrally formed with the photograph rendering apparatus 200 or separable therefrom.

Preferably, the ambient lighting system 216a changes the ambient lighting to reproduce a lighting for at least one of the time when the digital photograph was taken or the location where the digital photograph was taken. The ambient lighting system 216a can include one or more illumination means disposed in the area proximate the display 302, such as in the room 301. The illumination means is preferably one or more LED's disposed throughout the room. The LED's may be placed on or in the walls of the room or may be disposed in the components of the system 300. For example, the LED's 304 may be disposed in a frame around the display portion 302a of the display 302. In another example, the LED's 306 may be disposed on speakers 308 in the room 301. As an alternative, the illumination means may comprise other types of lighting devices. As a first example, if the location stamp indicates the digital still photograph was taken in Hawaii, the lighting system 216a can recreate, via the LED's, the type of light encountered in Hawaii. Furthermore, if the time stamp indicates that the digital still photograph being displayed was also taken during sunset in Hawaii, the lighting system 216a can recreate a sunset from Hawaii. Thus, a local ambiance is created in the room 301 corresponding to the digital photograph being displayed on the display 302, thereby, enriching the viewing experience for the viewers of the digital photograph. The lighting system 216a and/or photograph rendering apparatus 200 can access a remote database, such as database 216b or the Internet 216c by any wired or wireless means known in the art to determine the lighting conditions to be recreated for any given location and/or time. Such a determination may be automatically determined or manually chosen from a list by a user.

In another embodiment, the ambient characteristic can comprise reproducing audio in an area proximate the display, either by itself or in combination with the change in lighting. In this embodiment, the ambient alteration means can comprise an audio rendering system 216d and at least one speaker 308 operatively connected thereto. For example, when the photograph taken in Hawaii is being displayed on the display 302, the speakers may also reproduce the sound of Hawaiian music, waves, or spoken language. Furthermore, the audio reproduced may also be based on the time stamp. For example, if the time stamp indicates that the digital photograph was taken eight years ago, the audio rendering system 216d may reproduce a popular song of the time period when the digital photograph was taken. The audio rendering system 216d and/or photograph rendering apparatus 200 can access a remote database, such as the database 216b or Internet 216c by any wired or wireless means known in the art to determine any corresponding audio to be reproduced for any given location and/or time. Such audio may be automatically chosen or manually selected from a list by a user.

In yet another embodiment, the system 300 (or apparatus 200) can further comprise at least one other display 310 in an area proximate the display, e.g., in the room 301. In this embodiment, the ambient characteristic can comprise the at least one other display(s) 310, and particularly, displaying images, video, advertisements etc., on the other displays 310 within the room 301. In a first example of this embodiment, a display on the other display(s) 310 can be representative of a historical period within the time when the digital photograph was taken and/or representative of a geographical location where the digital photograph was taken. For example, if the digital photograph being viewed on the display 302 is determined to have been taken in Hawaii, the other displays 310 can display images or video of waves or palm trees. If the digital photograph being viewed on the display 302 is determined to have been taken in the summer of 1995, the images or video displayed on the other displays 310 can be reminiscent from such period, such as historical events taking place in such period. The other displays 310 can also be the walls of the room 301 or items in the room 301 and the images or video can be projected thereon. Historical information used to generate and display the images or video on the other displays 310 can be stored in a historical database 216e or available remotely therefrom, such as through the Internet 216c. Still further, the other displays can be a picture-in-picture display 302b in the display portion 302a of display 302.

In another example, the other displays 310 can display advertisements based on at least one of the time or location stamps contained in the digital photograph being displayed on the display 302. In this example, the system 300 or apparatus 200 includes an advertisement generation means 216f for generating at least one of an audio or visual advertisement on the at least one other display 310 or speaker 308. For example, if the location stamp indicates that the digital photograph being viewed on the display 302 was taken in Orlando Fla., the advertisement generation means 216f can generate or retrieve advertisements for Walt Disney World or other amusement company and display the same on the other displays 310. Furthermore, the advertisement generation means 216f can generate or retrieve Disney songs and reproduce the same on the speakers 308 while the digital still photograph is being viewed on the display 302. The time stamp can also be used to generate an advertisement display or audio. For example, the time stamp can indicate that the digital photograph being viewed on the display 302 was taken in Orlando Fla. during spring break. Thus, the advertisement can include displaying a special offer for the following spring break on at least one or at least a portion of the other displays 310. The advertisement information used to generate and display the advertisement content on the other displays 310 can be stored in the advertisement generation means 216f or available remotely therefrom, such as through the Internet 216c. Preferably, commercial companies would subscribe to a service for such advertisement. Such payment can be for each use or for a geographical area.

In all of the examples given above, the digital photographs viewed can be part of a slideshow containing a plurality of digital photographs. In such a situation, there is preferably a smooth transition from the recreated lighting as well as any audio or images reproduced from one photograph to another as they are being viewed. Such transitions may include fading out lighting, images, and/or audio associated with one photograph being viewed and fading in lighting, images, and/or audio associated with the next photograph being viewed. The fading does not have to be to or from normal ambient conditions but may be to or from an interim lighting, images and/or audio that provides a smoother transition. In order to minimize the amount of transition, the group of photographs in the slideshow may be analyzed by the system 300 (or component thereof, such as the apparatus 200) and group photographs together in sub-groups which contain similar time and/or location stamps and display the photographs in such sub-groups successively. In this manner, the greater transitions may be necessary only between sub-groups and the transitions between photographs in any sub-group may be eliminated or reduced.

The methods of the present invention are particularly suited to be carried out by a computer software program, such computer software program preferably containing modules corresponding to the individual steps of the methods. Such software can of course be embodied in a computer-readable medium, such as an integrated chip or a peripheral device.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

1. An apparatus for viewing digital still photographs, the apparatus comprising:
data input means for inputting at least one digital data file representing a digital still photograph, the at least one digital data file having at least one of a time and location stamp indicating a time when the photograph was taken or a location where the photograph was taken, respectively;
a display for displaying the digital still photograph;
digital still photograph rendering means for inputting the at least one digital data file to the display for rendering of the corresponding digital still photograph on the display; and
ambient alteration means for altering an ambient characteristic based on at least one of the time and location stamps.

2. The apparatus of claim 1, wherein the data input means is a media drive for reading the at least one digital data file from a media contained in the media drive.

3. The apparatus of claim 2, wherein the media drive is one of a CD player, DVD player, floppy drive, and digital camera media card reader.

4. The apparatus of claim 1, wherein the data input means comprises a modem operatively connected to one of a network, storage device, and digital still camera.

5. The apparatus of claim 1, wherein the data input means comprises a connector operatively connected through a cable to one of a network, storage device, and digital still camera.

6. The apparatus of claim 1, wherein the data input means comprises a connector wirelessly connected to one of a network, storage device, and digital still camera.

7. The apparatus of claim 1, wherein the ambient alteration means comprises a lighting system and the ambient characteristic comprises an ambient lighting in an area proximate the display.

8. The apparatus of claim 7, wherein the lighting system changes the ambient lighting to reproduce a lighting characteristic of at least one of the time when the digital photograph was taken and the location where the digital photograph was taken.

9. The apparatus of claim 1, wherein the ambient alteration means comprises an audio rendering system and at least one speaker operatively connected thereto and wherein the ambient characteristic comprises reproducing audio in an area proximate the display.

10. The apparatus of claim 9, wherein the reproduced audio is characteristic of at least one of the time when the digital photograph was taken and the location where the digital photograph was taken.

11. The apparatus of claim 1, further comprising at least one other display in an area proximate the display, wherein the ambient characteristic comprises the at least one other display.

12. The apparatus of claim 11, wherein a display on the one other display is representative of a historical period within the time when the digital photograph was taken.

13. The apparatus of claim 11, wherein a display on the one other display is representative of a geographical location where the digital photograph was taken.

14. The apparatus of claim 11, wherein the ambient alteration means comprises an advertisement generation means for generating at least one of an audio or visual advertisement on the at least one other display or a speaker operatively connected to the apparatus.

15. The apparatus of claim 11, wherein the one other display comprises a picture-in-picture display displayed on the display.

16. An apparatus for viewing digital still photographs, the apparatus comprising:
data input means for inputting at least one digital data file representing a digital still photograph, the at least one digital data file having at least one of a time and location stamp indicating a time when the photograph was taken or a location where the photograph was taken, respectively;
digital still photograph rendering means for inputting the at least one digital data file to a display for rendering of the corresponding digital still photograph; and
signal generation means for generation of a signal for altering an ambient characteristic based on at least one of the time and location stamps.

17. A method for viewing digital still photographs, the method comprising:
inputting at least one digital data file representing a digital still photograph, the at least one digital data file having at least one of a time and location stamp indicating a time when the photograph was taken or a location where the photograph was taken, respectively;
displaying the digital still photograph; and
altering an ambient characteristic based on at least one of the time and location stamps.

18. The method of claim 17, wherein the altering comprises altering an ambient lighting in an area proximate the display.

19. The method of claim 18, wherein the altering of the ambient lighting comprises at least one of reproducing a lighting for the time when the digital photograph was taken and the location where the digital photograph was taken.

20. The method of claim 17, wherein the altering comprises reproducing audio in an area proximate the display.

21. The method of claim 20, wherein the audio reproduced is characteristic of at least one of the time when the digital photograph was taken and the location where the digital photograph was taken.

22. The method of claim 17, wherein the altering comprises controlling at least one other display in an area proximate the display.

23. The method of claim 22, wherein the controlling comprises displaying indicia on the one other display representative of a historical period within the time when the digital photograph was taken.

24. The method of claim 22, wherein the controlling comprises displaying indicia on the one other display representative of a geographical location where the digital photograph was taken.

25. The method of claim 22, wherein the controlling comprises displaying an advertisement on the at least one other display.

26. A display comprising:
a display portion for rendering images; and
an illumination means separate from the display portion for illuminating an area proximate the display portion to change the lighting in the area.

27. A speaker comprising:
an audio reproduction means for reproducing audio in an area proximate the audio reproduction means; and
an illumination means for illuminating the area to change the lighting in the area.
